(19) United States
(12) Patent Application Publication
(10) Pub. No.: US 2011/0095633 A1
(43) Pub. Date: Apr. 28, 2011

(54) Magical Power

(76) Inventor: Chi Hong Le, Liverpool, NY (US)

(21) Appl. No.: 12/607,039

(22) Filed: Oct. 27, 2009

(51) Int. Cl. H02K 7/09; H01L 29/66; H02K 53/00

(52) U.S. Cl. 310/90.5; 257/212; 415/916; 257/E29.166

(57) ABSTRACT

Electric generator also can generate from silicon magnetic and quartz material by attract and repulsion polarity of silicon magnetic north and south apply force compress and decompress on quartz material to create electric signal. The other useful of silicon magnetic can keep holes charge at bay to create more free flow of electrons that help silicon switching faster and low heat.

### CROSS-REFERENCE TO RELATED APPLICATIONS

Not Applicable

### STATEMENT REGARDING FEDERALLY SPONSORED RESEARCH OR DEVELOPMENT

Not Applicable

### REFERENCE TO A SEQUENCE LISTING, A TABLE, OR A COMPUTER PROGRAM, LISTING COMPACT DISC APPENDIX

Not Applicable

### BACKGROUND OF THE INVENTION

### Field of Invention

This invention relates generally to generate electric and switching in semiconductor by spintronic. The characteristic of magnetic the same pole is repelled each others, difference poles are attractive together that have a lot of application in motor, generator. The latest material just discover is mono magnetic, so use both mono and bipolar magnetic turn into enclosing object floating in space or vacuum, frictionless, with initial magnetic pulses that make object rotate forever in theory, but will harvest the energy in long term is more than the energy input, with magnetic sensors convert to electrical current.

In process to make battery such lithium battery is embedded with silicon magnetic and quartz to help battery stay longer supply electrical current. In process to make silicon device is embedded silicon magnetic along side transistor gate to help transistor switching faster, with less current draw.

### BRIEF SUMMARY OF THE INVENTION CONTAINS NO NEW MATTER

Use mono, silicon magnetic, and quartz to generate electric. The same type of mono magnetic is repulsion each other, while silicon magnetic can alternate the polarity that excite the mono ball spin, also apply force compress and decompress on quartz, only small portion of electrical apply to silicon magnetic that lead to create more electrical current charge to the battery.

The silicon magnetic can attract the hole charge, while repulsion the electron charge that characteristic help transistor switching faster, and reduce the collision between hole and electron, therefore reduce resistance lead to reduce heat in semiconductor.

### BRIEF DESCRIPTION OF THE SEVERAL VIEWS OF THE DRAWING CONTAINS NO NEW MATTER

FIG. 1 is diagram showing enclosure and object are both them use north mono magnetic material, so they never touch each other because the character of magnetic, the same pole is repelled each others, result the object will be floated in inside the enclosure. The reason use vacuum inside the enclosure is avoid fiction when the object rotation.

FIG. 2 is diagram showing enclosure and object use south mono magnetic material.

FIG. 3 is diagram showing silicon magnetic layer or network of bipolar magnetic is surrounding outside the enclosure, to excite the object rotate, and sense the magnetic field convert to electrical.

FIG. 4 is block diagram showing energy generator circuit block diagram, consist of network magnetic pulses driver, mono magnetic, network magnetic collector, charger, and battery. The network magnetic pulses drivers take power from battery to generate magnetic pulses, or use silicon signal generator to rotate mono magnetic, when mono magnetic rotate will create more magnetic field output than magnetic field input, have advance the object floating rotate and without friction because inside the vacuum, the object and the enclosure are always repelling each other. Therefore, the object is completely controlled by the network magnetic pulses such as direction, and speed rotation. The network magnetic collector is silicon magnetic or bipolar magnetic and coils, from the start magnetic pulses that make mono magnetic rotate, then magnetic collector that all of three factors create multiplier magnetic field, more magnetic field then more electron flow, more current flow to charge the battery.

FIG. 5 is diagram showing silicon signal generator, silicon quartz layer is in between silicon magnetic layer. The silicon magnetic layer act like bipolar magnetic, so the two layer of magnetic are attract and repel each other, create push and pull force on the quartz layer, therefore create the current flow.

FIG. 6 is diagram showing silicon magnetic is keep holes charge at bay, so electrons are more freely to flow. Therefore, IC is less heat. Semiconductor get hot while is running because resistance of conflict between electrons and holes. More free electrons are flow that makes IC run faster and cooler. The other technique to make IC run less heat, the buses have high speed, high data rate, high bandwidth use nano fiber optic instead of copper. Use phase clock that make IC performance faster, and less heat. For instance, single clock is 1 GHz, if use phase clocks 0, 90, 180, 270, make IC run 1 GHz clock, but performance as IC use 4 GHz single clock.

### DETAILED DESCRIPTION OF THE INVENTION CONTAINS NO NEW MATTER

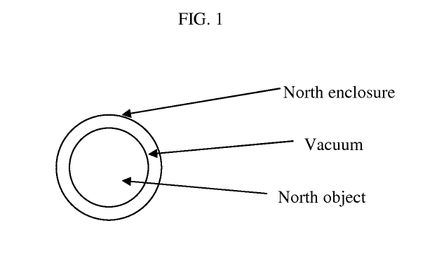

FIG. 1, Enclosure and Object are both them use North mono magnetic material, so they never touch each other because the character of magnetic, the same pole is repelled each others, result the object will be floated in inside the enclosure. The reason use vacuum inside the enclosure is avoid fiction when the object rotation.

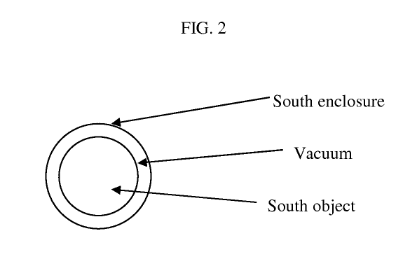

FIG. 2, Enclosure and Object use South mono magnetic material.

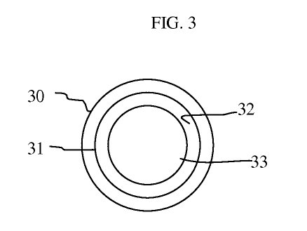

FIG. 3, Silicon magnetic layer or network of bipolar magnetic is surrounding outside the Enclosure, to excite the object rotate, and sense the magnetic field convert to electrical. Label 30 is silicon magnetic layer or network bipolar magnetic. Label 31 is enclosure mono magnetic layer. Label 32 is space vacuum. Label 33 is object inner mono magnetic layer.

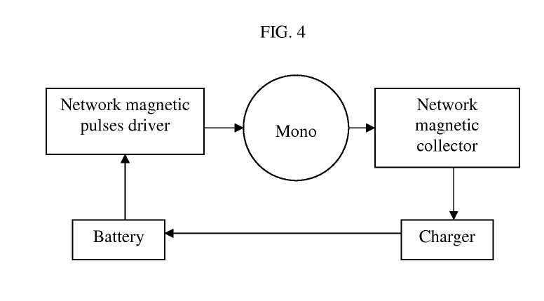

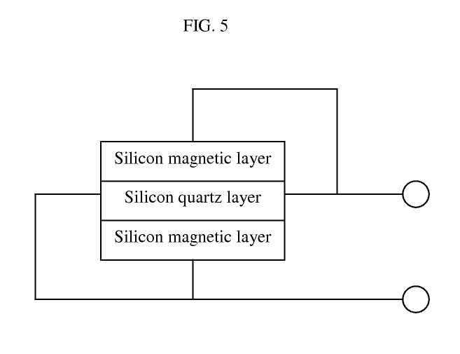

FIG. 4, Energy generator circuit block diagram, consist of network magnetic pulses driver, mono magnetic, network magnetic collector, charger, and battery. The network magnetic pulses drivers take power from battery to generate magnetic pulses, or use Silicon Signal Generator, FIG. 5, to rotate mono magnetic, when mono magnetic rotate will create more magnetic field output than magnetic field input, have advance the object floating rotate and without friction because inside the vacuum, the object and the enclosure are always repelling each other. Therefore, the object is completely controlled by the network magnetic pulses such as direction, and speed rotation. The network magnetic collector is silicon magnetic or bipolar magnetic and coils, from the start magnetic pulses that make mono magnetic rotate, then magnetic collector that all of three factors create multiplier magnetic field, more magnetic field then more electron flow, more current flow to charge the battery.

FIG. 5, Silicon signal generator block diagram, silicon quartz layer is in between silicon magnetic layer. The silicon magnetic layer act like bipolar magnetic, so the two layer of magnetic are attract and repel each other, create push and pull force on the quartz layer, therefore create the current flow.

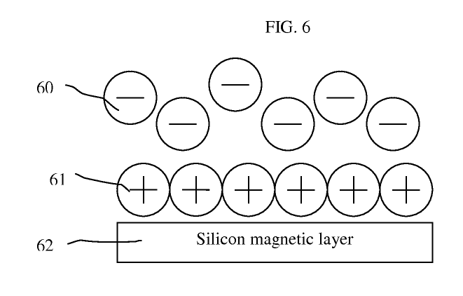

FIG. 6, silicon magnetic is keep holes charge at bay, so electrons are more freely to flow. Therefore, IC is less heat. Semiconductor get hot while is running because resistance of conflict between electrons and holes. More free electrons are flow that makes IC run faster and cooler. The other technique to make IC run less heat, the buses have high speed, high data rate, high bandwidth use nano fiber optic instead of copper. Use phase clock that make IC performance faster, and less heat. For instance, single clock is 1 GHz, if use phase clocks 0, 90, 180, 270, make IC run 1 GHz clock, but performance as IC use 4 GHz single clock. Label 60 is electron, negative charge. Label 61 is hole, positive charge. Label 62 is silicon magnetic acts like negative ion that attract positive charge, and repulsion negative charge.

What I claim as my invention is:

1. The device generates signal, and store energy.
The device regulates holes and electrons to make transistor switching faster and low heat.
